(19) United States
(12) Patent Application Publication
(10) Pub. No.: US 2004/0128266 A1
(43) Pub. Date: Jul. 1, 2004

(54) Method for optimizing energy consumption and cost

(75) Inventors: Krishna Kishore Yellepeddy, Austin, TX (US); Rabindranath Dutta, Austin, TX (US)

Correspondence Address: Darcell Walker, Ste. 250, 9301 S.W. Freeway, Houston, TX, 77074, US

(73) Assignee: INTERNATIONAL BUSINESS MACHINES CORPORATION, ARMONK, NY

(21) Appl. No.: 10/735,207

(22) Filed: Dec. 12, 2003

Related U.S. Application Data
(62) Division of application No. 09/931,305, filed on Aug. 16, 2001.

(51) Int. Cl. G01R 11/56

(52) U.S. Cl. 705/412; 700/291

(57) ABSTRACT

The present invention enables a facility (home, business or industrial site) to optimize the consumption of energy in that facility. In this invention, the power companies that supply energy provide information to its client facilities on the cost and availability of energy from that company on a real-time basis. Each client facility would have a power accounting server. These servers store this and process this information to predict when the rates for using the energy will be the least expensive for a particular task or to operate a particular appliance. A homeowner (client facility) for example can program appliances such as a dishwasher or laundry machine to turn on when the cost of energy is below a particular threshold price. The present invention has the capability to receive characteristics about a particular appliance, generate a list of energy consumption options for that particular product at a particular time period and select and implement the most efficient energy supply option. This invention can also enable a client facility that generates energy to efficiently use the generated energy and sell any excess energy to another end user or to other energy consumers.

### FIELD OF THE INVENTION

This invention describes a method for optimizing energy costs in a home and in particular to a method for implementing the most economical energy usage through the determination of the best time to use energy and the best source of that energy.

### BACKGROUND OF THE INVENTION

Utility companies generate traditional forms of energy such as natural gas and electricity for public consumption. In the prior art, each utility company has a service area in which it enjoys near-monopoly status. The utility company is obligated to supply the electric energy needs of individual customers within the service area. Of course, the demand for different forms of energy can vary according to a number of factors. In the long run, the demand for energy is a function of the population and industries within the service area. In the short run, energy demands vary according to many factors. Extreme weather, in particular, can significantly strain the generation capacity of the utility company.

Electric Power Systems are systems for the transformation of other types of energy into electrical energy and the transmission of this energy to the point of consumption. The production and transmission of energy in the form of electricity is relatively efficient and inexpensive. Electric power systems make possible the use of hydroelectric power at a distance from the source.

FIG. 1 shows the configuration of a conventional power generation and distribution process. This electric power system consists of three main components: the central power station 110, the substations 111 at which the power is stepped down to the voltage on the subtransmission lines, and the end user which could include residential customers 112, the business complexes 113 and industrial facilities 114. Other components of the electric power system include a set of transformers to raise the generated power to the high voltages used on the transmission lines, the transmission lines, the subtransmission lines; and the transformers that lower the subtransmission voltage to the level used by the consumer's equipment.

The central power station 110 comprises a prime mover, such as a turbine driven by water or steam, which operates a system of electric motors and generators. Most of the world's electric power is generated in steam plants driven by coal, oil, nuclear energy, or gas, with lesser percentages generated by hydroelectric, diesel, and internal-combustion plants.

Modern electric power systems use transformers to convert electricity into different voltages. This voltage is transmitted over lines usually composed of wires of copper, aluminum, or copper-clad or aluminum-clad steel, which are suspended from tall latticework towers of steel by strings of porcelain insulators.

In most parts of the world, local or national electric utilities have joined in grid systems. The linking grids allow electricity generated in one area to be shared with others. Each pooling company gains an increased reserve capacity, use of larger, more efficient generators, and compensation, through sharing, for local power failures.

These interconnected grids are large, complex machines that contain elements operated by different groups. These complex systems offer the opportunity for economic gain, but increase the risk of widespread failure. For example, a major grid-system breakdown occurred on Nov. 9, 1965, in eastern North America, when an automatic control device that regulates and directs current flow failed in Queenston, Ontario, causing a circuit breaker to remain open. A surge of excess current was transmitted through the northeastern United States. Generator safety switches from Rochester, N.Y., to Boston, Mass., were automatically tripped, cutting generators out of the system to protect them from damage. Power generated by more southerly plants rushed to fill the vacuum and overloaded these plants, which automatically shut themselves off. The power failure enveloped an area of more than 200,000 sq km (80,000 sq mi), including the cities of Boston, Buffalo, Rochester, and New York.

Similar grid failures, usually on a smaller scale, have troubled systems in North America and elsewhere. On Jul. 13, 1977, about 9 million people in the New York City area were once again without power when major transmission lines failed. In some areas the outage lasted 25 hours as restored high voltage burned out equipment. These major failures are termed blackouts. The term brownout is often used for partial shutdowns of power, usually deliberate, either to save electricity or as a wartime security measure. To protect themselves against power failures, hospitals, public buildings, and other facilities that depend on electricity have installed backup generators.

Over the period from 1950 to 1998, the most recent year for which data are available, annual world electric power production and consumption rose from slightly less than 1,000 billion kilowatt hours (kwh) to 13,616 billion kwh. A change also took place in the type of power generation. In 1950, about two-thirds of the electricity came from thermal (steam-generating) sources and about one-third from hydroelectric sources. In 1998 thermal sources produced 63 percent of the power, but hydropower had declined to 19 percent, and nuclear power accounted for 17 percent of the total. The growth in nuclear power slowed in some countries, notably the United States, in response to concerns about safety. Nuclear plants generated 19 percent of U.S. electricity in 1998; in France, the world leader, the figure was 76 percent.

In order to provide reliable service for their customers, utility companies arrange their transmission and distribution lines in networks or grids. When any portion of the grid fails, power is supplied along alternate routes. Neighboring utilities have extended this principle by intertying their transmission systems to provide additional reliability. In addition, many utilities have formed power pools. In a power pool, central power dispatching centers control the generation, transmission, and distribution of power for all the utilities in the pool.

Currently, energy supply processes are experiencing a transformation from regulated utility companies to deregulation. This deregulation will eliminate or greatly modify the operation of the current utility company monopolies. Although the intent is to create competition and reduce the cost of energy, with energy deregulation, the cost of energy can become prohibitively expensive. If the demand for energy exceeds the supply, the condition is exacerbated even more. Until recently, home users did not make extraordinary efforts to conserve electrical energy, as it was relatively inexpensive. With the current spiraling energy prices seen in states such as California, home users are becoming increasingly conscious of the need to conserve energy. For example, prices in California average approximately $330.00 megawatt-hour currently. This rate is approximately 11 times higher than a year ago. Thus, the cost of power that is provided to home users can fluctuate dramatically under deregulation.

The demand for electricity has increased each year because of increasing industrialization. Concurrently, there has been a widening search for new sources of energy and new ways to turn energy into electricity. In particular, electric utility companies the world over have been searching for new ways to meet the tremendous future demand for electricity. For instance, the United States used roughly 2 trillion kilowatt-hours in 1975 and it is estimated that its usage was at least 8 trillion kilowatt-hours in year 2000.

Many utility companies also have been looking for economical means to meet their peak loads. Utilities that are unable to stay ahead of their customers' peak demands for electricity reduce the voltage of the power they deliver. This low-voltage power causes light bulbs to dim, elevators and subways to run slowly, and air-conditioning units to function poorly. However, even those utilities that resort to voltage reductions usually can easily meet their loads most of the time. Their most difficult periods generally occur in the mid-afternoon during prolonged heat waves. Widespread use of air conditioning consumes tremendous amounts of electricity, and this places a severe strain on many utilities ability to meet their load demands during the hottest hours of midsummer days.

In seeking ways to meet the ever-increasing demand for power, two lines of attack are being investigated. One is to find new or unexploited energy sources. These sources include solar energy, geothermal energy, and nuclear energy. The other line of attack is to find new ways to exploit present energy more efficiently, for instance by developing super-conducting power lines.

Distributed electric power generation is technology that places small modular power generation units close to the end-users. This technology constitutes a new concept and approach within the modern power industry. This new approach can have a significant impact on the future development of the power system structure. A study by the Electric Power Research Institute (EPRI), for example, indicates that by 2010, 25% of the new power generated will be distributed power generation. A study by the Natural Gas Foundation concluded that this figure could be as high as 30%.

Regulatory changes and improvements in the performance and cost of some modular generation technologies make the application of modular generation systems an attractive approach to meet customers' needs while delivering electricity at prices sometimes lower than electricity generated at central station power plants, then transmitted through the grid. Distributed power can be used to provide power to customers while deferring transmission and distribution investment and can improve power quality and reliability.

Distributed generation has seen limited applications to date. Crucial regulatory, economic and institutional issues will determine the ultimate rate and scope of implementation of distributed power generation. In partnership with its member companies, the U.S. Department of Energy (DOE), EPRI and other stakeholders, GRI is working to qualify the potential value of distributed generation, develop decision-making tools, and improve selected technologies targeted for use in distributed generation applications.

The transmission and distribution (T&D) system represents a growing share of the capital investments made electric utility companies. Distributed generation offers a cost-effective means of meeting growing peak demands for existing customers and serving new commercial or industrial customers on T&D systems already near capacity, while avoiding expensive T&D upgrades.

Based on assumptions in ABB Incorporated's guidebook, “Introduction to Integrated T&D Planning”, it can cost $365 to $1,100 per kW to run a six-mile power line to 3 MW customers. Small distributed generation systems driven by gas turbines or reciprocating engines generally cost $600 to $900 per kW in this instance and are competitive in the higher end of the range. Fuel cells, another alternative power technology, cost about the $3,000 per kW, but their quiet operation, ultra-low emissions, potential for heat recovery, and high efficiency can offer great value in specific cases where reliable power quality is critical and environmental restraints are demanding.

Although these distributed power generation systems may be the start to a reduction in energy consumption and a more efficient use of energy, there remains a need for a process that can further advance the ability of a user to maximize the creation and consumption of energy.

### SUMMARY OF THE INVENTION

It is an objective of this invention to provide a method for optimizing energy usage and production at the user end.

It is a second objective of this invention to provide a method for determining a cost for generating energy at the end user site.

It is a third objective of the invention to provide an available price for selling energy generated by an end user to another energy consumer.

It is a fourth objective of the invention to provide a method for an end-user to purchase energy generated by another end-user at the site of the purchasing end-user.

It is a fifth objective of the invention to provide a method for establishing an optimal schedule for using and generating energy at the end user site.

It is a sixth objective of this invention to provide an accounting program that is used to buy and sell energy directly to other co-generating end user sites.

It is a seventh objective of the invention to monitor energy costs and prices over various periods of time.

The present invention enables an end-user facility (home, business or industrial site) to optimize the consumption of energy in that facility. In this invention, energy suppliers would make available to end-users information about the price and availability of energy from that supplier. This information would be available on a real-time basis. The various forms of energy could include solar, gas, and electric energy. These end-user facilities will gather and process this information to determine when the rates for using the energy will be the least expensive for a particular task or to operate a particular appliance. A homeowner for example can program appliances such as a dishwasher or laundry machine to turn on at a time when the cost of energy of a supplier is below a particular threshold price and receive energy from that particular supplier to operate the appliance. The present invention has the capability to receive energy use characteristics about a particular appliance, generate a list of energy consumption options for that particular appliance over a particular time period and select and implement the most efficient energy supply option.

This invention can also enable a facility that generates energy to efficiently use the generated energy and sell any excess generated energy to another end user or to a power supply company. In an example, the end-user may have generated a surplus of electrical energy. The end-user would decide the quantity of energy that they wanted to sell and the selling price. The user would make this information available to potential users for example by storing it on a server that other potential users could access. If an end-user desires to buy the energy from the end-user, the actual sale could also occur over the communication network.

### DESCRIPTION OF THE DRAWINGS

FIG. 1 is a conventional power generation and distribution process for electrical energy.

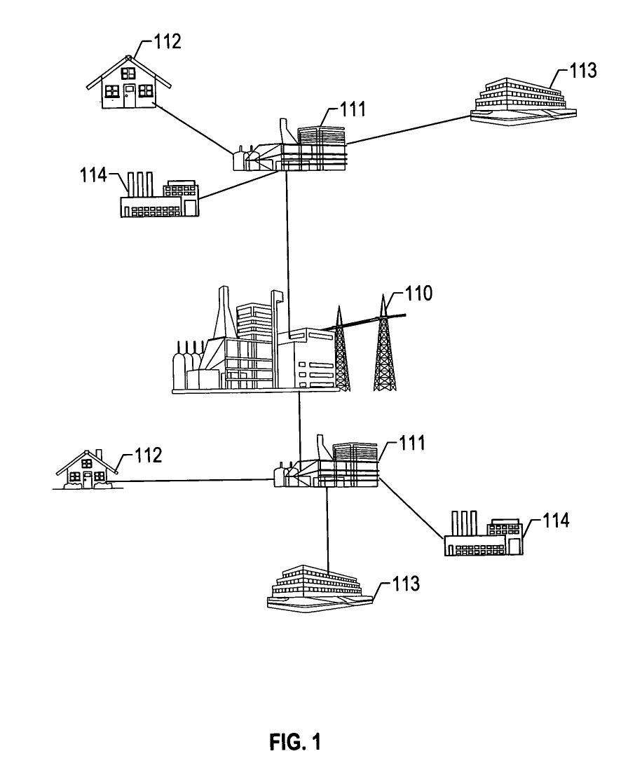

FIG. 2 is a distributed power generation process for electrical energy.

FIG. 3 is a configuration of a system for optimizing energy cost and usage as described in the present invention.

FIG. 4 is a flow diagram for determining optimal power usage from one power source.

FIG. 5 is an example of the information provided by energy companies concerning price and availability of energy from that utility company.

FIG. 6 is a flow diagram for determining optimal energy usage from multiple power sources.

FIG. 7 is a flow diagram for determining, selecting and implementing an optimal energy usage option.

FIG. 8 depicts data processing equipment a system that can be utilized to implement the present invention.

FIG. 9 is a diagram of a computer over which messages and transactions may be transmitted.

FIG. 10 is a sample of the electrical grid connecting several utilities.

FIG. 11 is a flow diagram of the process of selling energy generated by a user to other users and to utility companies.

### DETAILED DESCRIPTION OF THE INVENTION

The present invention provides a method to optimize the consumption of energy at a facility. This facility could be a residential home, an office building or even an industrial facility such as a chemical plant. This invention can be implemented in a context where the facility itself generates or creates energy as well as if the facility only consumes energy. The types of energy can vary and could include any form of energy that powers devices. Although, the method of the invention applies to any form of energy, the description of this invention will be mainly in the context of the generation and consumption of electrical energy.

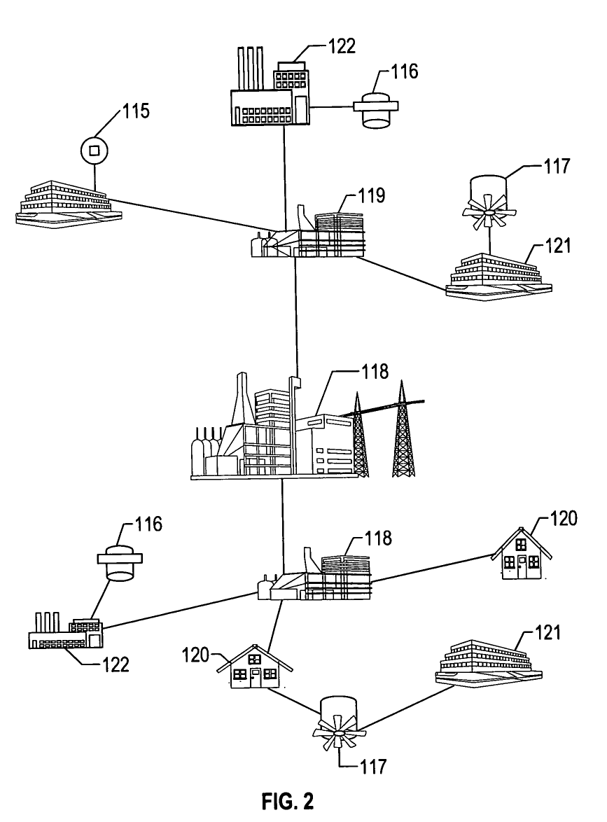

FIG. 2 illustrates an example of a proposed distributed power generation system configuration for the present invention. As shown, the power generation devices can include a fuel cell 115, a gas turbine 116, a reciprocating engine 117, a central station 118 and substation 119. The central station and substation represent convention power generated by a utility company. The end users are residential customers 120, commercial customers 121 and industrial customers 122. The end users can have connections to multiple power generating devices. In one example, a commercial customer 121 can have connections to a reciprocating engine 117 and a substation 119. In addition, power-generating devices can have connections to various end users.

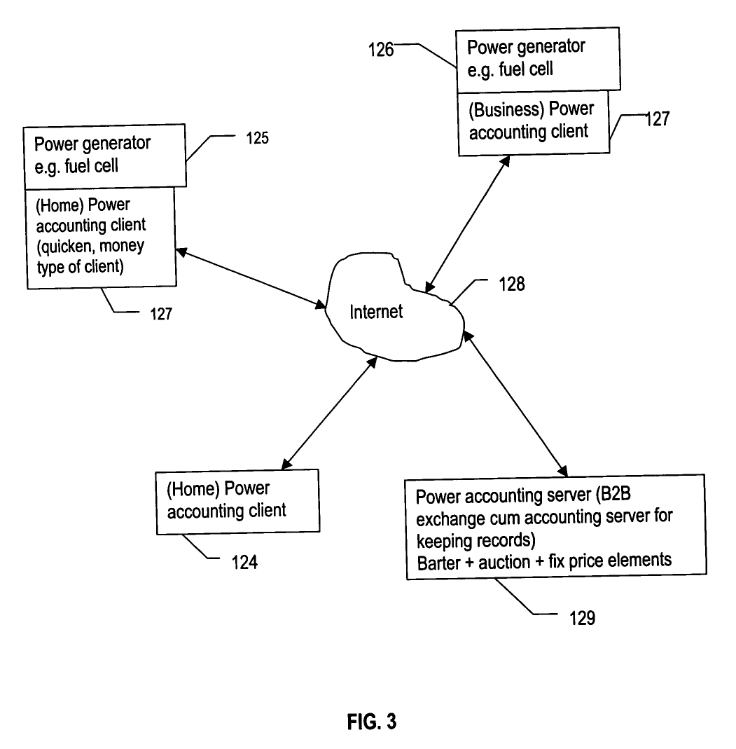

Referring to FIG. 3, there is a configuration of the implementation of the present invention. As shown, there are various types of end-users that will be part of the power generation and distribution process. End-user 124 is the traditional home end-user that does not generate any power from their home. End-user 125 is a home end-user that also generates energy. End-user 126 is a business that uses and generates energy. All of the end-users have power accounting software 127 that can calculate, forecast and recommend optimal times and sources for use of energy. These end-users are connected to each other via a global computing network such as the internet 128. A power accounting server 129 connects to each end-user via the internet. This server can contain information about energy availability, energy type, price, and supplier name. The server can enable the dynamic updating of information such as price, supplier etc. This server can keep records about energy consumption trends, energy price variations and energy quantities. The accounting server 129 server can also contain energy compensation options such as bartering. An end-user that produces electricity may exchange the electrical energy that they produce for natural gas energy produced by another energy supplier.

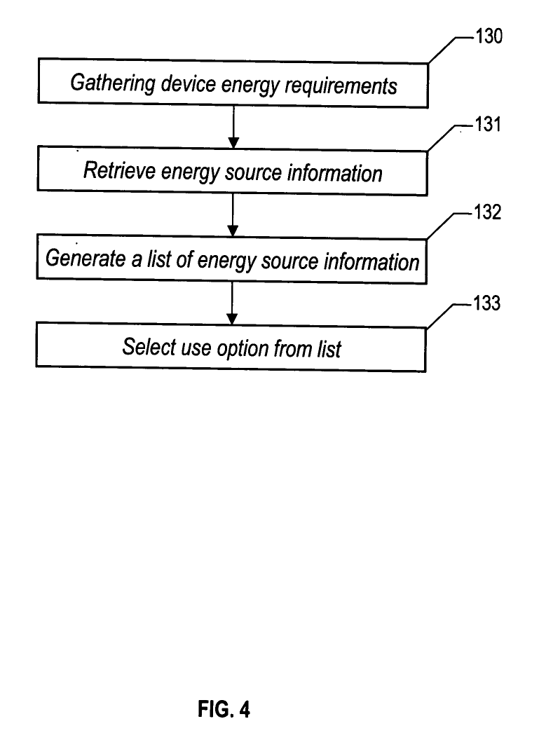

The methods of the present invention can be implemented in various energy consumption configurations. FIG. 4 illustrates a flow diagram for determining the optimal energy usage from one energy source. In this particular application, information about the various devices or appliances is gathered 130 and supplied to the power accounting program of the particular end-user. This information could be for a dishwasher appliance or other home or business device that requires energy to operate. The information would include the standard dishwasher operating cycle time, the type of energy required by the dishwasher (most dishwashers use electricity, however, some appliances use natural gas), and the quantity of energy usually required in a typical operation. The next step is to retrieve information concerning the availability of energy from the energy suppliers 131. This information would be typically located in the power accounting server 129. This information would consist of the quantity of energy that is available at various times and the price of the energy at the various times. For example, energy at a peak time such as the early evening hours could have a higher rate than energy at non-peak hours such as early morning hours. Once the accounting program 127 has retrieved the energy supplier information, the accounting program generates a list 132 of the optimum energy alternatives based on the appliance's energy requirements and the available energy by the suppliers. The next step 133 would be to select a desirable energy option from the list. This selection could be based on an end-user energy policy, which contains conditions under which the accounting program will buy energy. An example of an energy policy would be to not buy energy priced over an established threshold price. The end-user may decide that it is optimal to use energy generated by the end-user, if available, instead of purchasing the energy from an alternate source. This process can apply to multiple appliances seeking energy from one energy source.

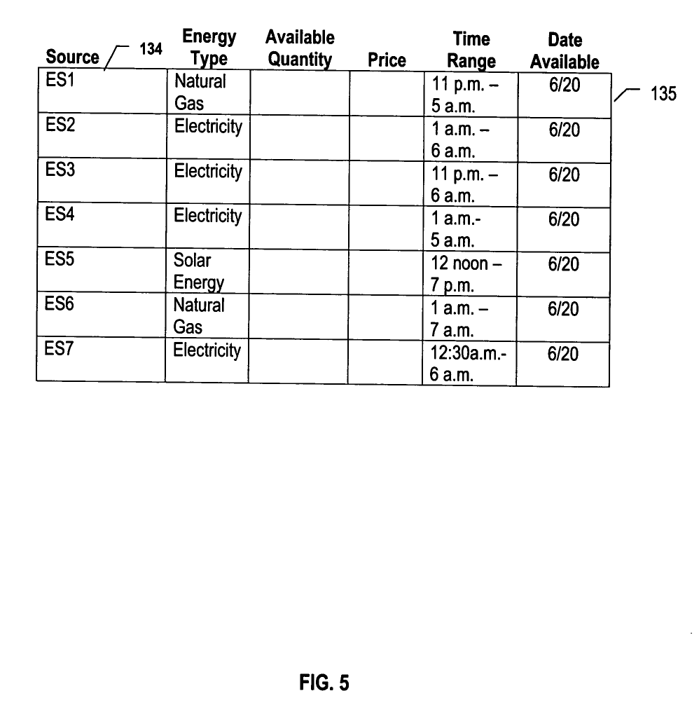

FIG. 5 is illustrates a display of information on the availability of energy from various energy suppliers. As shown, this information includes categories such as type of energy, quantity of energy, price of energy, time range of availability and date of availability for each energy supplier in the particular system. This arrangement is an example of a way to represent energy information from the various energy suppliers in one location. In this table representation of data, each energy supplier 134 could have an entry record 135 containing fields that would hold information about the various energy characteristic categories. This type of format can allow for easy data retrieval, sorting and analysis. The accounting program generates a list 132 of the optimum energy alternatives based on the appliance's energy requirements and the available energy by the supplier. The accounting program could generate the list in step 132 by searching the “Energy Type” field in table. A search of this field would quickly produce a list of all energy suppliers with a specific type of energy such electricity this is available for purchase by consumers.

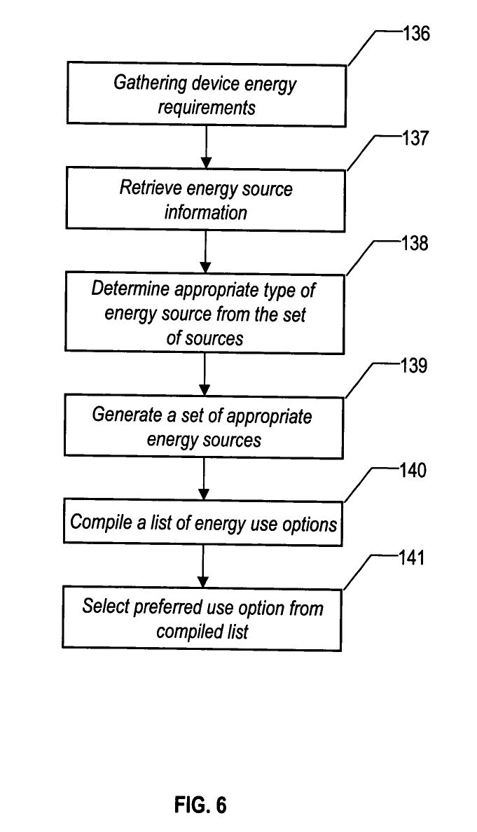

FIG. 6 illustrates a flow diagram for determining the optimal energy usage from multiple energy sources. As with the process illustrated in FIG. 4, information about the various devices or appliances is gathered 136 and supplied to the power accounting program of the particular end-user. The information would include an appliance's operating cycle time, the type of energy required by the appliance, and the quantity of energy usually required in a typical operation. Step 137 retrieves information concerning the availability of energy from the various energy suppliers. This information for each energy supplier could include the type of energy available, the quantity of energy availability over a particular time range and the price of the energy. Other information about the suppliers could be whether the particular supplier would consider a barter transaction in which the parties would trade one form of energy for another form of energy or options to purchase energy through an auction.

Once the accounting program 127 has retrieved the energy supplier information, the accounting program makes a determination of which energy suppliers have the appropriate type of energy for the requesting end-user 138. The energy suppliers having the desired energy type are included in a set of appropriate energy sources for that application 139. From this set of energy sources, the control program compiles a list 140 of the optimum energy alternatives based on the appliance's energy requirements and the available energy by each supplier. This calculation results in a list of suppliers that an end-user could consider.

This calculation involves matching the appliance requirements with the best available energy supplier option. For example, the energy supplier that can supply the desired energy type, in a sufficient quantity, at the preferred time and for the best price will receive a recommendation as the best option. The program can also rank the requirements such that price has more importance than time of day. However, the appropriate energy type and the quantity of energy would have more importance than the price. If the energy supplier was a natural gas supplier, but the need was for electricity, that supplier would not receive any consideration because that energy type does not match the required energy type. This supplier would not appear in the set generated in step 139. Furthermore, if the quantity of energy available from a supplier is less than the amount required by the appliance to complete the operating cycle, there would not be a match between the end-user and the energy supplier. This supplier would also not appear on this list generated in step 140. A gain, the end-user may choose one of the energy sources based a set of criteria or the end-user could decide to user their own generated energy 141.

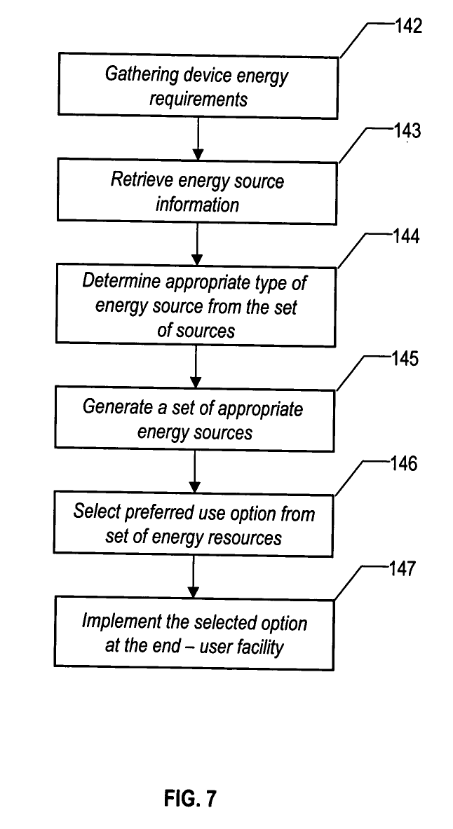

FIG. 7 illustrates a flow diagram for determining, selecting and implementing an optimal energy usage option from multiple energy sources. As with the process illustrated in FIG. 6, information about the various end-user devices or appliances is gathered 142 and supplied to the power accounting program of the particular end-user. Step 143 retrieves information concerning the availability of energy from the various energy suppliers. Once the accounting program 127 has retrieved the energy supplier information, the accounting program makes a determination of which energy suppliers have the appropriate type of energy for the requesting end-user 144. The energy suppliers having the desired energy type are included in a generated set of appropriate energy sources for that application 145. From this set of energy sources, the control program selects a preferred resource to provide the energy for a particular appliance or application 146. After selection, the program controller implements a pre-programmed operation of the particular appliance or application 147 using energy from the selected energy according to the information gathered in step 142. This use could be automatically implemented in step 147 through the program controller.

The selection of an energy source could be through process similar to steps 140 and 141 as previously discussed in FIG. 6. Another energy source selection process could be through a series of one-to-one comparison of energy sources. This process would not need to compile a list of energy alternatives. In this process, each comparison would result in the determination of the best energy option between the two compared energy sources. The process would use this option in the next comparison. The completion of all comparisons would result in the best energy option. This option would be selected and implemented in step 147. An example of this process could involve four energy options, including generating the energy at the end-user facility. This particular example would require three comparisons. The result could be that generating the energy at the end-user is the best energy option.

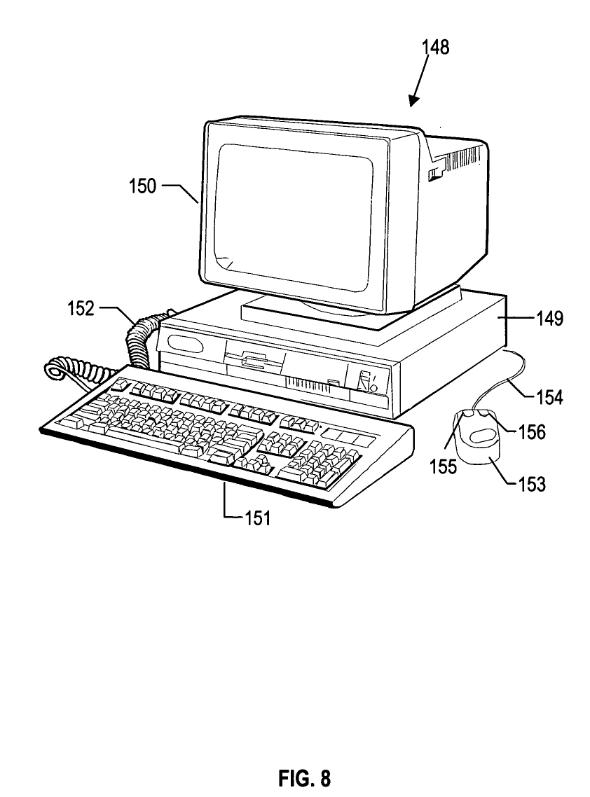

FIG. 8 illustrates a pictorial representation of data processing system 148 which may be used in implementation of the present invention. As may be seen, data processing system 148 includes processor 149 that preferably includes a graphics processor, memory device and central processor (not shown). Coupled to processor 149 is video display 150 which may be implemented utilizing either a color or monochromatic monitor, in a manner well known in the art. Also coupled to processor 150 is keyboard 151. Keyboard 151 preferably comprises a standard computer keyboard, which is coupled to the processor by means of cable 152. Also coupled to processor 149 is a graphical pointing device, such as mouse 153. Mouse 153 is coupled to processor 149, in a manner well known in the art, via cable 154. As is shown, mouse 153 may include left button 155, and right button 156, each of which may be depressed, or “clicked”, to provide command and control signals to data processing system 148. While the disclosed embodiment of the present invention utilizes a mouse, those skilled in the art will appreciate that any graphical pointing device such as a light pen or touch sensitive screen may be utilized to implement the method and apparatus of the present invention. Upon reference to the foregoing, those skilled in the art will appreciate that data processing system 148 may be implemented utilizing a personal computer.

Once the accounting software 127 is installed on the general purpose processing system 148, connections are made to the various energy appliances in a facility. At this point, the computer system 148 becomes a special purpose system. The facilities with these special systems are known as “smart facilities”.

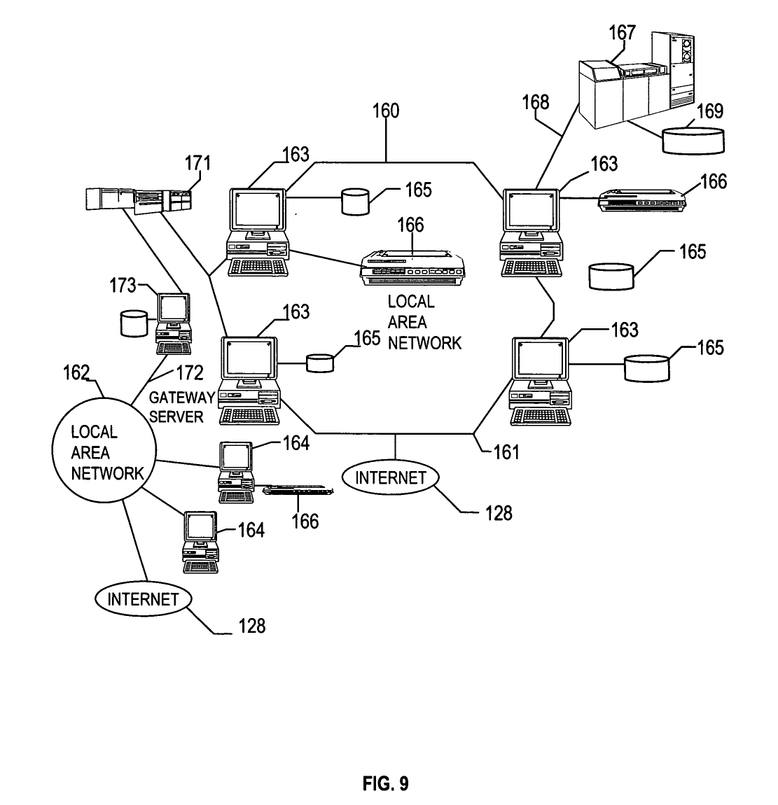

The method of the present invention may be implemented in a global computer network environment such as the Internet 128. With reference now FIG. 9, there is depicted a pictorial representation of a distributed computer network environment 160 in which one may implement the method and system of the present invention. As may be seen, distributed data processing system 160 may include a plurality of networks, such as Local Area Networks (LAN) 161 and 162, each of which preferably includes a plurality of individual computers 163 and 164, respectively. Of course, those skilled in the art will appreciate that a plurality of Intelligent Work Stations (IWS) coupled to a host processor may be utilized for each such network. Any of the processing systems may also be connected to the Internet as shown. As is common in such data processing systems, each individual computer may be coupled to a storage device 165 and/or a printer/output device 166. One or more such storage devices 165 may be utilized, in accordance with the method of the present invention, to store the various data objects or documents which may be periodically accessed and processed by a user within distributed data processing system 160, in accordance with the method and system of the present invention. In a manner well known in the prior art, each such data processing procedure or document may be stored within a storage device 165 which is associated with a Resource Manager or Library Service, which is responsible for maintaining and updating all resource objects associated therewith.

Still referring to FIG. 9, it may be seen that distributed data processing system 160 may also include multiple mainframe computers, such as mainframe computer 167, which may be preferably coupled to Local Area Network (LAN) 161 by means of communications link 168. Mainframe computer 167 may also be coupled to a storage device 169 which may serve as remote storage for Local Area Network (LAN) 161. A second Local Area Network (LAN) 162 may be coupled to Local Area Network (LAN) 161 via communications controller 171 and communications link 172 to a gateway server 173. Gateway server 173 is preferably an individual computer or Intelligent Work Station (IWS), which serves to link Local Area Network (LAN) 162 to Local Area Network (LAN) 161. As discussed above with respect to Local Area Network (LAN) 162 and Local Area Network (LAN) 161, a plurality of data processing procedures or documents may be stored within storage device 169 and controlled by mainframe computer 167, as Resource Manager or Library Service for the data processing procedures and documents thus stored. Of course, those skilled in the art will appreciate that mainframe computer 167 may be located a great geographical distance from Local Area Network (LAN) 161 and similarly Local Area Network (LAN) 161 may be located a substantial distance from Local Area Network (LAN) 164. That is, Local Area Network (LAN) 164 may be located in California while Local Area Network (LAN) 161 may be located within Texas and mainframe computer 167 may be located in New York.

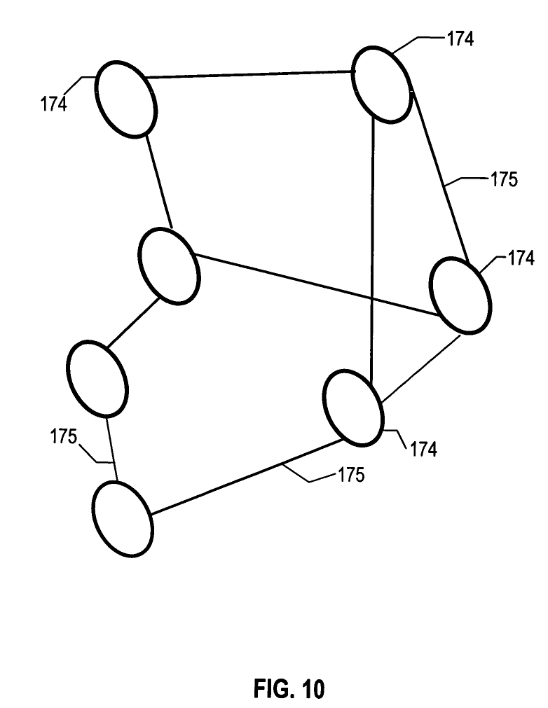

In addition to providing a method and system to optimally purchase and user energy, the present invention provides a mechanism through which an End-user can sell or trade surplus energy created by that End-user to other end-users or to other energy suppliers. The technology described in FIG. 10 is especially applicable in this type of energy selling application. There are various schemes through which energy trades can occur. In a convention configuration that can be used in the energy trading process, an electric energy grid exists, as shown in FIG. 10, which connects each utility's generating facilities to other utility generating facilities. In these cases, each circle 174 represents an individual utility company. Each line 175 represents high-voltage lines, which form the grid between the various utilities. Electric energy is traded between utility companies and other market participants to meet shortfalls in capacity during unit outages, to achieve cost savings, or to increase revenues. “Bulk transactions” refers to the wholesale buying and selling of electrical energy. Typically, the parties involved in these trades are traditional electric utility companies. These companies wish to meet their obligations to provide reliable service to their customers in the most economically feasible manner. Often it is possible for a utility to purchase electricity from a neighboring utility more economically than it could produce it for itself. At other times, the power generator can sell excess generation at a price higher than its cost of generation.

In the conventional process of trading for utilities, companies determine which trades are the most economical. To determine which trades are economic, utility companies produce sophisticated forecasts of load (required generation) so that they can schedule their generators to run efficiently. The system dispatcher then determines if demand is likely to be over or under projections during various times of the day. The dispatcher is also interested in the associated cost with each level of generation. Even though the load forecasts are sophisticated, actual conditions usually deviate from them. These deviations may be due to a number of circumstances, such as having generating units go off-line unexpectedly, differences between forecast and actual weather conditions, or changes in the price of available fuel to run the generators. All of these events affect the costs to produce various forms of energy. Because of changes in these forecasts, the dispatcher telephones neighboring utility companies to determine prices and quantities of energy available for upcoming hours. These calls occur many times a day, sometimes hourly. At the same time, dispatchers for other utilities are also making phone calls. If the dispatcher finds what he considers to be a good deal, a trade is consummated. The result is that deals are often struck before the phone surveys are complete. It is rare for a dispatcher to call beyond his direct neighboring utility companies. This means that the opportunity for more economic transactions may have been overlooked simply because the dispatcher did not know about them. This particular energy trading method has manual implementation.

Recent technology developments have produced energy trading systems that automate energy trading using the telephone. These automated methods of trading energy allow utilities to simultaneously view real-time market prices and energy availabilities and to quickly consummate the best opportunities. These methods consider available transmission capacity, and calculate and schedule the least cost path for the energy. These systems can also report the transactions, invoice the participating parties, and facilitate rapid collection and disbursement of funds. Some systems allow for anonymous trading required of a true market.

One method for trading electric energy that could conceptually be implemented in the present invention is described in U.S. Pat. No. 6,115,698 to Tuck et al. This method establishes a nationwide electronic information system that assists electricity suppliers purchasing and selling electricity by providing a common marketplace. With this method, participants to gather market information and make energy transactions decisions based on the best available opportunities. This method involves a software application, a computer and communications network, and a central server. It allows users to enter quantity and price information on energy that they have available to sell, wish to buy, or both. These offers are then sorted and presented to other system Participants. These offers are sorted by lowest price to highest for purchase opportunities and sorted highest price to lowest for sale opportunities. Each Participant sees delivered price for purchases and total revenue for sales from its unique location in the electric grid.

This method also allows the buyers and sellers of electrical energy to offer different degrees of firmness for their energy. There are systems that assist in maintaining the reliability of the electric grid by using a conservative method to schedule available transmission capacity. Each Participant maintains the amount of transmission capacity made available for transactions each hour. As transactions are consummated, this capacity is consumed and is no longer available for use by others. This feature helps assure that the transmission systems do not become unintentionally overloaded. Allowing simultaneous, electronic notification of all parties to a transaction upon a transaction's curtailment augments reliability. There are services that provide monthly billing and Electronic Funds Transfer (EFT) services for payments and disbursements to all Participants as part of the basic package. This feature allows Participants to trade with more companies than they would otherwise and to manage their invoicing and collections with their current levels of staffing.

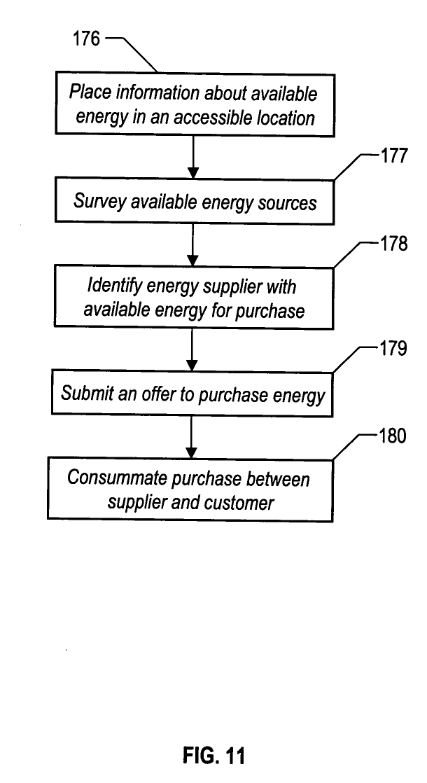

FIG. 11 illustrates a method through which an end-user could sell surplus energy generated by that end-user. The end-user that desires to sell surplus energy would submit information about the available energy to other potential energy purchasers 176. This submission could be to a central storage location such as a server. Another form of submission could direct submissions to other end-users that exist on the same communication network. As with other previously described purchasing methods, the potential purchasers would survey or review the submission 177. Once a potential purchaser indicates in the energy available from this end-user supplier 178, that purchaser would submit an offer to the energy supplier 179. This offer could be in the form of acceptance of the purchasing price and amount or it could be a counter-offer with a proposed price. If the supplier accepts the response including any counter offer, there would be consummation of the purchase between the buyer and the seller 180. If the supplier does not accept any counter offer in the response, there could be a period of negotiation in which the parties would exchange offers until there was an agreement or until the parties chose to discontinue negotiations for the purchase of energy between the parties.

It is important to note that while the present invention has been described in the context of a fully functioning data processing system, those skilled in the art will appreciate that the processes of the present invention are capable of being distributed in the form of instructions in a computer readable medium and a variety of other forms, regardless of the particular type of medium used to carry out the distribution. Examples of computer readable media include media such as EPROM, ROM, tape, paper, floppy disc, hard disk drive, RAM, and CD-ROMs and transmission-type of media, such as digital and analog communications links.

We claim:

1. A method for optimizing energy consumption and energy cost at an end-user facility comprising the steps of:
gathering information about energy consumption requirements of an end-user;
retrieving information on the availability of energy supplied by energy suppliers to end-users;
compiling a list of energy usage options, for energy consumption of a particular device within a particular time period, based on energy consumption requirements and energy availability, said energy use options including energy supply entities and end-users that generate energy;
selecting the energy use option from the compiled list that provides the optimal energy use for a particular device; and
implementing the selected energy use option at the end-user facility.

2. The method as described in claim I wherein said gathering information step comprises determining the number of devices of the user that require the consumption of energy in order to operate.

3. The method as described in claim 2 wherein said information gathering step further comprises gathering information on each such device of the user, such information comprising the amount of time that the device will be operating, the preferred time of day for operating the device, the types of energy required by the device and the amount of energy typically use by the device in standard operations.

4. The method as described in claim 3 wherein said information retrieval step comprises retrieving information on each energy resource, such information comprising the types of energy provided by the resource, the amount of energy available over a particular time range, and the price of the energy of the particular time range.

5. The method as described in claim 4 wherein said compilation of optimal energy use options list comprises the steps of:
creating, from energy consumption requirements information, an energy consumption policy for each device that will consume energy;
creating an energy availability profile from the information retrieved on each energy source;
comparing the energy requirements of a device for which energy is desired with the available energy from the energy resources; and
generating a list of optimal energy resources based on said comparisons.

6. The method as described in claim 5 wherein the selection of an energy resource is based on a match between the amounts of energy required by a device for operation and the quantity of energy available from each of the energy suppliers during a particular time range.

7. The method as described in claim 5 wherein said selection and implementation steps are automatically performed based on established end-user energy consumption policies.

8. A method for optimizing energy usage at an end user site comprising the steps of:
determining a cost for generating energy at the end user site;
determining the cost of purchasing energy from another energy supplier;
establishing a set of end-user energy policies for generating and using energy at the end-user facility; and
generating a set of energy supply alternatives based on the energy user requirements and the cost of the energy alternatives.

9. The method as described in claim 8 further comprising after said generating step, the step of selecting an energy alternative that provides optimal energy usage, said selection being based on said established end-user energy policies.

10. The method as described in claim 9 wherein said end-user energy policy is based on the lowest energy cost and the closest available time to a preferred time of the user.

11. The method as described in claim 9 further comprising after said selection step, steps for implementing a pre-programmed operation of the particular appliance or application using energy from the selected energy option.

12. The method as described in claim 11 wherein said implementing steps are automatically performed.

13. The method as described in claim 9 further comprising when the selected alternative is the end-user the steps of:
generating energy at the end-user facility;
using said generated energy as desired by the end-user; and
selling any excess generated energy to other end-users or to energy suppliers.

14. The method as described in claim 13 wherein said energy selling step comprises:
placing information about available energy in a location accessible to potential energy purchasers;
negotiating the price and quantity of the energy with a potential energy purchaser; and
consummating the transaction with the potential energy purchaser.

15. The method as described in claim 14 wherein said negotiating step comprises:
receiving an offer from a potential purchaser to buy energy, said offer containing a desired energy quantity and purchase price;
determining whether to accept the offer, reject the offer or to submit a counter offer to the potential purchaser; and
submitting a response to the potential energy purchaser.

16. The method as described in claim 9 further comprising when the selected alternative is the end-user the steps of:
submitting an offer to purchase energy to the selected energy supplier;
receiving a response to the energy purchase offer from the selected energy supplier; and
consummating the transaction with the energy purchaser.

17. A system for optimizing energy consumption and energy cost at an end-user location comprising:
an end-user controller including an accounting program and a memory operatively connected to said accounting program, said controller capable of identifying energy usage options;
a terminal, adapted to enable an end-user to communicate with said controller for the purpose of transmitting information about appliance operating requirements to said accounting program;
an energy information storage facility for storing and maintaining information about available energy sources for the end-user;
a decision-making entity that automatically selects and implements an optimal energy option, the selection and implementation being based on an established end-user energy consumption policy; and
a communication network the enables communication between said end-user controller and said energy information storage facility.

18. The system as described in claim 17 wherein said end-user controller is adapted to retrieve from said storage facility information about energy options.

19. The system as described in claim 17 wherein said decision-making entity is contained in said end-user controller.

20. The system as described in claim 18 wherein said energy information storage facility is an energy accounting server.

21. The system as described in claim 20 wherein said accounting server contains information about available energy supplies, said information includes types of energy available, quantity of energy available from each energy supplier and price of energy from each energy supplier.

22. The system as described in claim 21 wherein said stored information is arranged such that information for each energy supplier is arranged in a record containing fields with the types of information in each field.

23. The system as described in claim 21 wherein said accounting server further contains information about energy compensation options such as bartering, auctions and fix prices.

24. A computer program product in a computer readable medium for optimizing energy usage at an end user site comprising:
instructions for determining a cost for generating energy at the end user site;
instructions for determining the cost of purchasing energy from another energy supplier;
instructions for establishing a schedule for generating and using energy at the user end; and
instructions for generating a set of energy supply alternatives based on the energy user requirements and the cost of the energy alternatives.

25. The method as described in claim 24 further comprising after said generating instructions, instructions for selecting an energy alternative that provides optimal energy usage, said selection being based on said established end-user energy policies.

26. The method as described in claim 25 further comprising after said selecting instructions, instructions for implementing a pre-programmed operation of the particular appliance or application using energy from the selected energy option.

27. The computer program product as described in claim 24 further comprising when the selected alternative is the end-user the instructions for:
generating energy at the end-user site;
using said generated energy as desired by the end-user; and
selling any excess generated energy to other end-users or to energy suppliers.

28. The computer program product as described in claim 27 wherein said energy selling instructions comprise:
instructions for placing information about available energy in a location accessible to potential energy purchasers;
instructions for negotiating the price and quantity of the energy with a potential energy purchaser; and
instructions for consummating the transaction with the potential energy purchaser.

29. The computer program product as described in claim 28 wherein said energy negotiating instructions comprise instructions for:
receiving an offer from a potential purchaser to buy energy, said offer containing a desired energy quantity and purchase price;
determining whether to accept the offer, reject the offer or to submit a counter offer to the potential purchaser; and
submitting a response to the potential energy purchaser.

30. The computer program product as described in claim 25 further comprising when the selected alternative is the end-user:
instructions for submitting an offer to purchase energy to the selected energy supplier;
instructions for receiving a response to the energy purchase offer from the selected energy supplier; and
instructions for consummating the transaction with the energy purchaser.

31. A computer program product in a computer readable medium for optimizing energy consumption and energy cost at an end-user facility comprising:
instructions for gathering information about energy consumption requirements of an end-user;
instructions for retrieving information on the a vailability of energy supplied by energy suppliers to end-users;
instructions for compiling a list of energy usage options for energy consumption for a particular device within a particular time period, based on energy consumption requirements and energy availability, said energy use options including supply entities and end-users that generate energy;
instructions for selecting the energy use option from the compiled list that provides the optimal energy use for a particular device; and
instructions for implementing the selected energy use option at the end-user facility.

32. The computer program product as described in claim 30 wherein said gathering information instruction further comprises instructions for determining the number of devices of the user that require the consumption of energy in order to operate.

33. The computer program product as described in claim 31 wherein said information gathering instruction further comprises gathering information on each such device of the user, such information comprising the amount of time that the device will be operating, the preferred time of day for operating the device, the types of energy required by the device and the amount of energy typically use by the device in standard operations.

34. The computer program product as described in claim 32 wherein said instruction for information retrieval of available energy resources comprises retrieving information on each energy resource, such information comprising the types of energy provided by the resource, the amount of energy available over a particular time range, and the price of the energy of the particular time range.

35. The computer program product as described in claim 34 wherein said instruction for compilation of optimal energy use options list further comprises:
instructions for creating, from energy consumption requirements information, an energy consumption policy for each device that will consume energy;
instructions for creating an energy availability profile from the information retrieved on each energy source;
instructions for comparing the energy requirements of a device for which energy is desired with the available energy from the energy resources; and
instructions for generating a list of optimal energy resources based on said comparisons.

36. The computer program product as described in claim 35 wherein the selection of an energy resource is based on a match between the a mounts of energy required by a device for operation and the quantity of energy available from each of the energy suppliers during a particular time range.

37. The computer program product as described in claim 35 wherein the selection of an energy resource is based on an optimal energy policy for the particular end-user device.
